(19) United States
(12) Patent Application Publication
(10) Pub. No.: US 2022/0394872 A1
(43) Pub. Date: Dec. 8, 2022

(54) SERVER

(71) Applicants: Inventec (Pudong) Technology Corporation, Shanghai (CN); INVENTEC CORPORATION, Taipei (TW)

(72) Inventors: Zhao GENG, Shanghai (CN); Guang-Zhao TIAN, Shanghai (CN); Li-Hong HUANG, Shanghai (CN)

(21) Appl. No.: 17/381,672

(22) Filed: Jul. 21, 2021

(30) Foreign Application Priority Data
Jun. 2, 2021 (CN) 202110615053.4

(51) Int. Cl. H05K 7/14; G06F 1/18; H05K 7/20

(52) U.S. Cl. CPC H05K 7/1487; G06F 1/181; G06F 1/187; G06F 1/185; H05K 7/20727

(57) ABSTRACT

A server comprises a cabinet, a computing node and a plurality of hard disk assemblies. The cabinet is provided with a computing node accommodating slot and a plurality of hard disk accommodating slots. The computing node is assembled in the computing node accommodating slot, wherein the computing node is not provided with any hard disk. The hard disk assemblies are respectively assembled in the hard disk accommodating slots, wherein each of the hard disk assemblies has a plurality of hard disks, and the plurality of hard disk is electrically connected to the computing node.

### CROSS-REFERENCE TO RELATED APPLICATIONS

This non-provisional application claims priority under 35 U.S.C. § 119(a) on Patent Application No(s). 202110615053.4 filed in China on, Jun. 2, 2021, the entire contents of which are hereby incorporated by reference.

### BACKGROUND

### 1. Technical Field

This disclosure relates to a server, especially for a blade server.

### 2. Related Art

Generally, a blade server includes a cabinet, a plurality of slots arranged in the cabinet, and a plurality of server nodes assembled in the slots. Each server node includes a motherboard, and the motherboard is provided with a central processing unit, a memory, various PCIE computing components and multiple hard disks. The shorter the distance between the hardware component and the central processing unit is, the higher the transmission rate between the hardware component and the central processing unit is and the shorter the signal delay time between the hardware component and the central processing unit is. On the contrary, the longer the distance between the hardware component and the central processing unit is, the slower the transmission rate between the hardware component and the central processing unit is and the longer the signal delay time between the hardware component and the central processing unit is. Since the transmission rate required for data storage is much lower than that required by the memory and the PCIE computing components, the memory and the PCIE computing components are usually near the central processing unit when configuring hardware components on the motherboard.

As for the hard disk, the distance between the hard disk and the central processing unit is longer than that between the memory (or PCIE computing component) and the central processing unit, and the hard disk is connected to the central processing unit through a longer cable.

Due to the increasing demand for data storage, the number of hard disks required by the server is increasing. However, at present, the number of hard disks that can be accommodated in each server node has reached an upper limit. In order to increase the number of hard disks that can be accommodated on each server node, there is indeed a need for an improved server architecture.

### SUMMARY

Accordingly, this disclosure provides a server, wherein the total number of hard disks that can be accommodated in the server is maximized without affecting the data transmission bandwidth of the server.

According to one or more embodiment of this disclosure, a server comprises a cabinet, a computing node and a plurality of hard disk assemblies. The cabinet is provided with a computing node accommodating slot and a plurality of hard disk accommodating slots. The computing node is assembled in the computing node accommodating slot, wherein the computing node is not provided with any hard disk. The hard disk assemblies are respectively assembled in the hard disk accommodating slots, wherein each of the hard disk assemblies has a plurality of hard disks, and the plurality of hard disk is electrically connected to the computing node.

According to one or more embodiment of this disclosure, a server comprises a cabinet, a first computing node, a second computing node, a network card, a hard disk assembly and a network interface controller. The cabinet is provided with a first computing node accommodating slot, a second computing node accommodating slot and a hard disk accommodating slot. The first computing node is assembled in the first computing node accommodating slot, wherein the first computing node is not provided with any hard disk.

The second computing node is assembled in the second computing node accommodating slot, wherein the second computing node is not provided with any hard disk. The network interface controller is connected to the first computing node and the second computing node, wherein a first working state of the first computing node is synchronized with a second working state of the second computing node. The hard disk assembly is assembled in the hard disk accommodating slot, wherein the hard disk assembly comprises a plurality of hard disks, and the hard disks are electrically connected to the first computing node and the second computing node.

In view of the above description, all of the hard disks are concentrated in the hard disk assembly and the computing node is not provided with any hard disk, thereby increasing the total number of hard disks that can be accommodated in the server. In addition, the computing node and the hard disk assembly may be used as independent modular nodes for being purchased individually. Besides convenient management, the cost for manufacturing the server may be reduced. Furthermore, according to the needs of business applications or the needs of power supply and load bearing of the server room, the ratio of the number of computing nodes to the number of hard disk assemblies may be flexibly configured to optimize the overall operating performance of the server. In addition, the first computing node is synchronized with the second computing node under normal conditions to use each other as a backup, which may improve the reliability and security of the server.

### BRIEF DESCRIPTION OF THE DRAWINGS

The present disclosure will become more fully understood from the detailed description given herein below and the accompanying drawings which are given by way of illustration only and thus are not limitative of the present disclosure and wherein:

FIG. 1 is a schematic diagram of the assembly of a server according to a first embodiment of this disclosure;

FIG. 2 is a functional block diagram of the circuit of the server according to the first embodiment of this disclosure;

FIG. 3 is a functional block diagram of the circuit of a hard disk assembly of FIG. 2;

FIG. 4 is a power transmission configuration diagram of the hard disk assembly of FIG. 2;

FIG. 5 is a schematic diagram of the assembly of a server according to a second embodiment of this disclosure;

FIG. 6 is a functional block diagram of the circuit of the server according to the second embodiment of this disclosure;

FIG. 7 is a functional block diagram of the circuit of a hard disk assembly of FIG. 6; and

FIG. 8 is a power transmission configuration diagram of the hard disk assembly of FIG. 6.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawings.

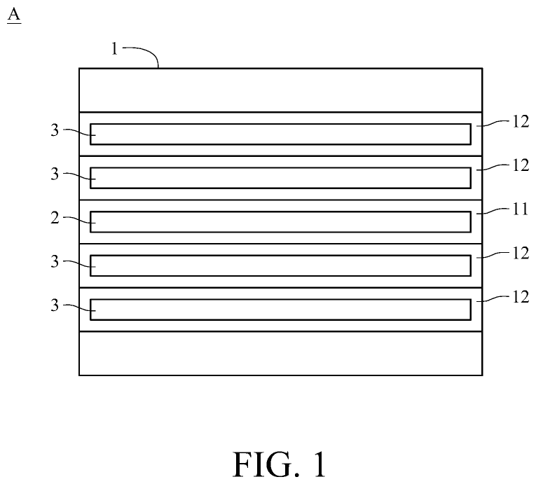

FIG. 1 is a schematic diagram of the assembly of a server according to a first embodiment of this disclosure. As shown in FIG. 1, the server A comprises a cabinet 1, a computing node 2 and a plurality of hard disk assemblies 3, and the cabinet 1 is provided with a computing node accommodating slot 11 and a plurality of hard disk accommodating slots 12. The computing node 2 is assembled in the computing node accommodating slot 11, wherein the computing node 2 comprises a baseboard management controller, a central processing unit, a memory, and PCIE computing components, but the computing node 2 is not provided with any hard disk. Each of the hard disk assemblies 3 may be a just a bunch of disks(JBOD), and the hard disk assemblies 3 are respectively assembled in the hard disk accommodating slots 12.

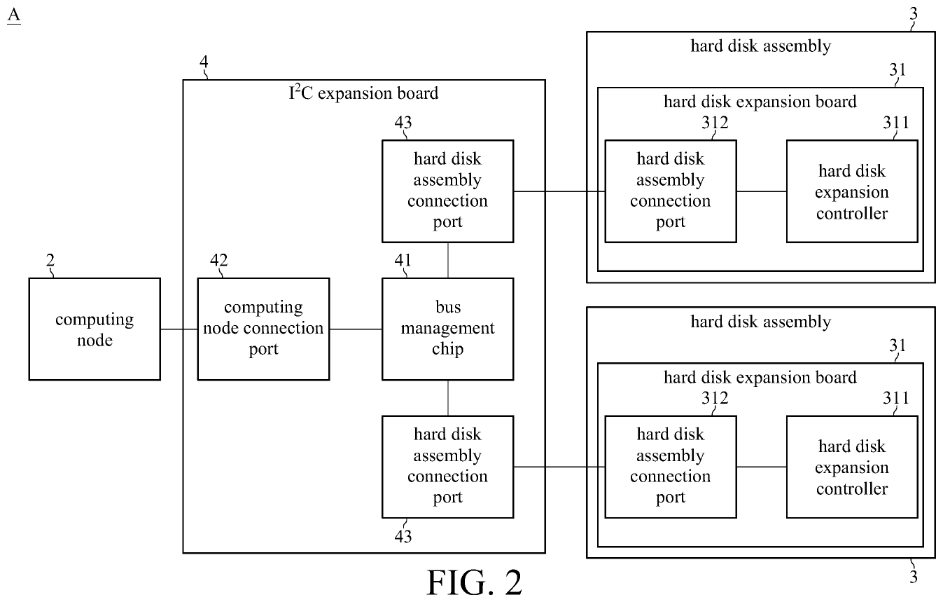

FIG. 2 is a functional block diagram of the circuit of the server according to the first embodiment of this disclosure. The server of FIG. 2 illustrates a circuit architecture of a computing node for monitoring the plurality of hard disk assemblies at the same time, and two of the hard disk assemblies are taken as an example. The server A comprises the computing node 2, two hard disk assemblies 3 and an inter-integrated circuit bus (I²C) expansion board 4. The computing node 2 is electrically connected to the hard disk assemblies 3 by the inter-integrated circuit bus expansion board 4. Each of the hard disk assemblies 3 comprises a hard disk expansion board 31, and the hard disk expansion board 31 is provided with a hard disk expansion controller 311 (whose product number is: SAS34X36R, for example) and a hard disk assembly connection port 312. The hard disk assembly connection port 312 may be an RJ45 port, and the hard disk expansion controller 311 is electrically connected to the hard disk assembly connection port 312 by the inter-integrated circuit bus (I2C). The inter-integrated circuit bus expansion board 4 is provided with a bus management chip 41, a computing node connection port 42 and a plurality of hard disk assembly connection ports 43. Each of the hard disk assembly connection ports 43 may be an RJ45 port, and the bus management chip 41 is electrically connected to the computing node connection port 42 and the hard disk assembly connection ports 43 by inter integrated circuit buses. The computing node connection port 42 is electrically connected to the baseboard management controller (whose product number is: AST2500, for example) of the computing node 2 by signal lines, and the hard disk assembly connection ports 43 are respectively electrically connected to the hard disk assembly connection ports 312 of the hard disk assemblies 3 by signal lines. In this way, the computing node 2 can update the firmware of the hard disk expansion controller 311 of each of the hard disk assemblies 3 and monitor the status of each of the hard disk assemblies 3 by the inter-integrated circuit bus expansion board 4.

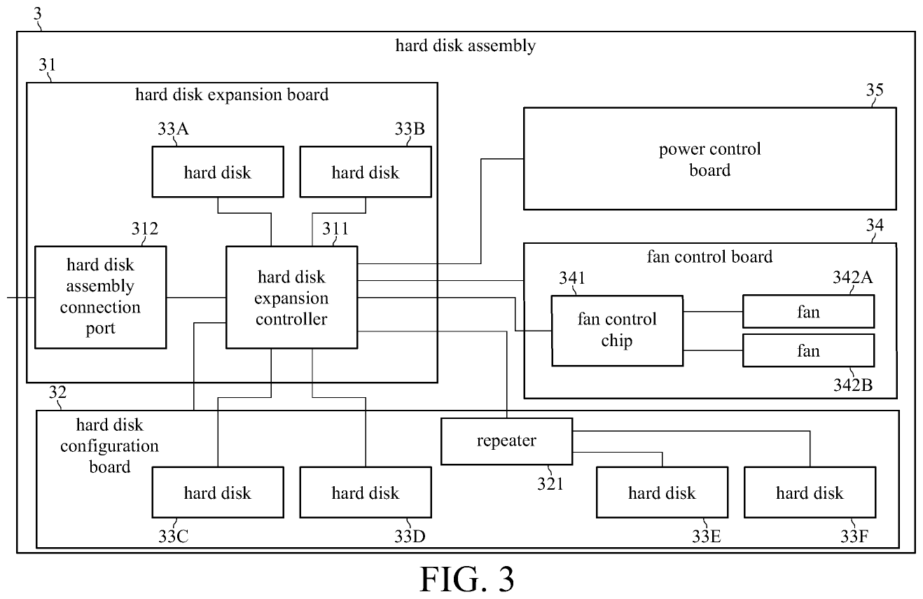

FIG. 3 is a functional block diagram of the circuit of a hard disk assembly of FIG. 2. As shown in FIG. 3, in addition to the hard disk expansion board 31, each of the hard disk assemblies 3 further comprises a hard disk configuration board 32, a plurality of hard disks 33A-33F, a fan control board 34 and a power control board 35. The hard disks 33A-33B are assembled to the hard disk expansion board 31, and the hard disks 33C-33F are assembled to the hard disk arrangement board 32. The hard disk expansion controller 311 is electrically connected to the hard disk configuration board 32, the power control board 34, and the fan control board 35 by inter-integrated circuit buses, and the hard disk expansion controller 311 is electrically connected to the hard disks 33A-33B mounted on the hard disk expansion board 31 and the hard disks 33C-33D mounted on the hard disk arrangement board 32 by SAS transmission lines. Since the hard disks 33E-33F are far away from the hard disk expansion controller 311, the hard disk configuration board 32 is further provided with a repeater 321, and the repeater 321 is electrically connected to the hard disk expansion controller 311 and the hard disks 33E-33F by SAS transmission lines. In this way, the hard disk expansion controller 311 can transmit SAS signals to the hard disks 33E-33F by the repeater 321. Furthermore, the computing node 2 can obtain the hard disk state information of each of the hard disks 33A-33F by the hard disk expansion controller 311, wherein the hard disk state information includes a hard disk rotation speed, a hard disk writing speed, and a hard disk reading speed. In addition, the hard disk expansion controller 311 may respectively enable the hard disk 33A-33F at different time to avoid excessive power consumption. The hard disk expansion controller 31 is further provided with an URAT interface, and the hard disk expansion board 3 is provided with a DB9 standard interface. The URAT interface is electrically connected to the DB9 standard interface. The DB9 standard interface is used as an external debugging serial port of the hard drive expansion controller 31.

The fan control board 34 is provided with a fan control chip 341 and a plurality of fans 342A-342B. The fan control chip 341 is a complex programmable logic device (CPLD), and the fan control chip 341 is electrically connected to the fans 342A-342B and the hard disk expansion controller 311. The computing node 2 obtains fan state information of each of the fans 342A-342B by the hard disk expansion controller 311 of each of the hard disk assemblies 3. For example, the fan state information can be a fan speed. The computing node 2 can also update firmware of the fan control chip 341 by the hard disk expansion controller 311. In addition, when the hard disk expansion controller 311 is abnormal, the fan control chip 341 will control the fans 342A-342B according to safety specifications.

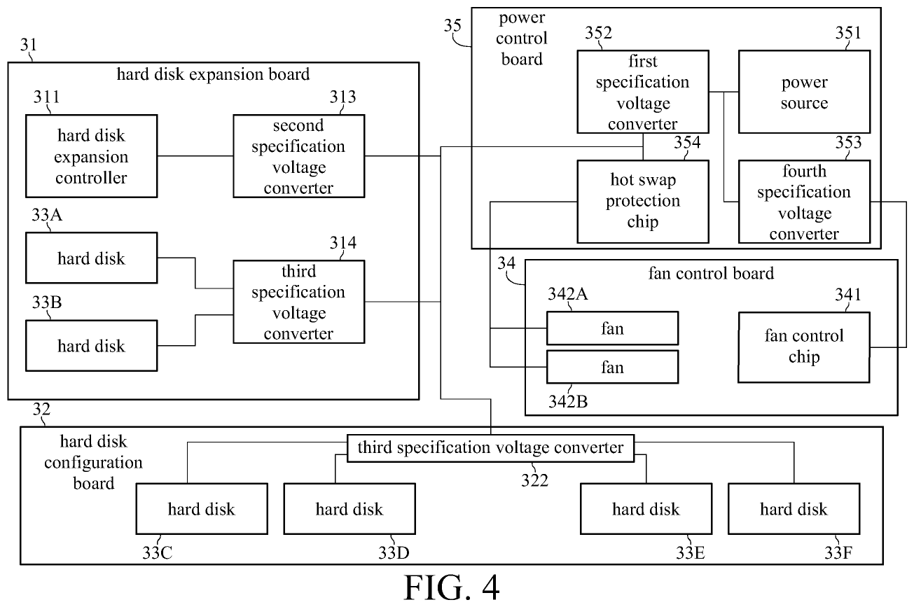

FIG. 4 is a power transmission configuration diagram of the hard disk assembly of FIG. 2. As shown in FIG. 4, the power control board 35 is provided with a power source 351 and a first specification voltage converter 352, wherein the output voltage of the power source 351 is 48V, the first specification voltage converter 352 is a 48V to 12V converter, the first specification voltage converter 352 has an input terminal and an output terminal, and the input terminal of the first specification voltage converter 352 is electrically connected to the power source 351. The hard disk expansion board 31 is provided with a second specification voltage converter 313 and a third specification voltage converter 314, and the hard disk configuration board 32 is provided with another third specification voltage converter 322, wherein the second specification voltage converter 322 is a 12V to 1.8V converter, and the third specification voltage converters 314 and 322 are 12V to 5V converters respectively. The second specification voltage converter 313 has an input terminal and an output terminal. The input terminal of the second specification voltage converter 313 is electrically connected to the output terminal of the first specification voltage converter 352, and the output terminal of the second specification voltage converter 313 is electrically connected to the hard disk expansion controller 311. The third specification voltage converter 314 has an input terminal and an output terminal. The input terminal of the third specification voltage converter 314 is electrically connected to the output terminal of the first specification voltage converter 352, and the output terminal of the third specification voltage converter 314 is electrically connected to the hard disks 35A-35B. The third specification voltage converter 322 has an input terminal and an output terminal. The input terminal of the third specification voltage converter 322 is electrically connected to the output terminal of the first specification voltage converter 352, and the output terminal of the third specification voltage converter 322 is electrically connected to the hard disks 35C-35F.

The power control board 35 is further provided with a fourth specification voltage converter 353 and a hot swap protection chip 354. The fourth specification voltage converter 353 is a 48V to 3.3V converter, and the fourth specification voltage converter 353 has an input terminal and an output terminal. The input terminal of the fourth specification voltage converter 353 is electrically connected to the power source 351, and the output terminal of the fourth specification voltage converter 353 is electrically connected to the fan control chip 341 of the fan control board 34. The hot swap protection chip 354 has an input terminal and an output terminal. The input terminal of the hot swap protection chip 354 is electrically connected to the output terminal of the first specification voltage converter 352, and the output terminal of the hot swap protection chip 354 is electrically connected the fans 342A-342B mounted on the fan control board 34 for supporting hot swap functions of the fans 342A-342B.

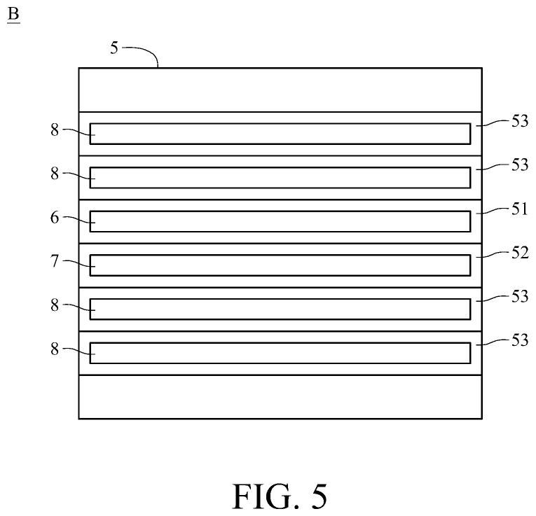

FIG. 5 is a schematic diagram of the assembly of a server according to a second embodiment of this disclosure. As shown in FIG. 5, a server B comprises a cabinet 5, a first computing node 6, a second computing node 7, and a plurality of hard disk assemblies 8.

The cabinet 5 is provided with a first computing node accommodating slot 51 and a second computing node accommodating slot 52 and a plurality of hard disk accommodating slots 53. The first computing node 6 is assembled in the first computing node accommodating slot 51. The first computing node 6 comprises a baseboard management controller, a central processing unit, a memory, and PCIE computing components, but the first computing node 6 is not provided with any hard disk. The second computing node 7 is assembled in the second computing node accommodating slot 52. The second computing node 7 comprises a baseboard management controller, a central processing unit, memory, and PCIE computing components, but the second computing node 7 is not provided with any hard disk. Each of the hard disk assemblies 8 may be a just a bunch of disks (JBOD), and hard disk assemblies 8 are respectively assembled in the hard disk accommodating slots 53.

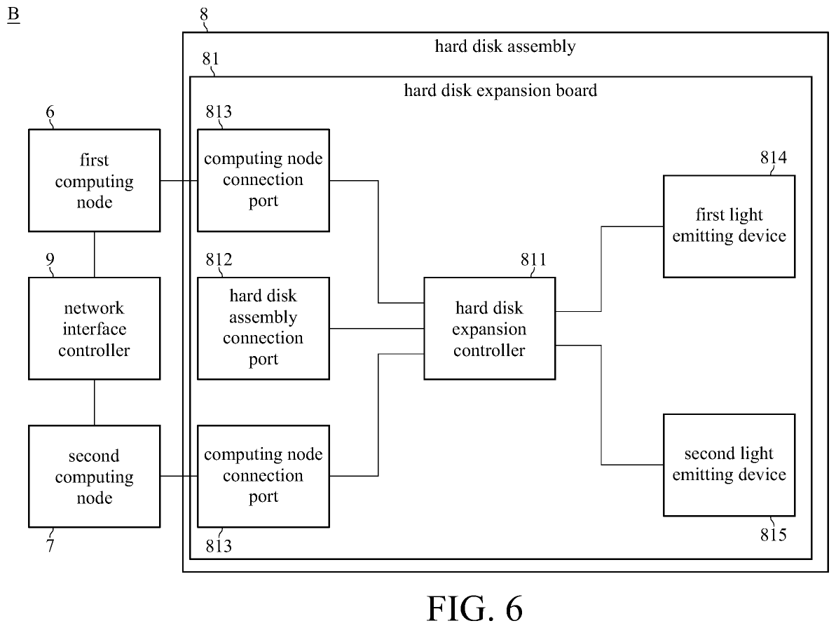

FIG. 6 is a functional block diagram of the circuit of the server according to the second embodiment of this disclosure. The server of FIG. 6 illustrates a circuit architecture of two computing node for monitoring a hard disk assembly at the same time, and one of the hard disk assemblies is taken as an example. A server B comprises a first computing node 6, a second computing node 7, a hard disk assembly 8, and a network interface controller 9. The network interface controller 9 is electrically connected to the first computing node 6 and the second computing node 7. The hard disk assembly 8 comprises a hard disk expansion board 81. The hard disk expansion board 81 is provided with a hard disk expansion controller 811, a hard disk assembly connection port 812, and a plurality of computing node connection ports 813. The disk expansion controller 811 and the hard disk assembly connection port 812 are respectively similar to the hard disk expansion controller 311 and the hard disk assembly connection port 312 of FIG. 2. Each of the computing node connection ports 813 may be a SF8644 port. The hard disk expansion controller 811 is electrically connected to the computing node connection ports 813 by SAS signal lines, and the computing node connection ports 813 are electrically connected to the first computing node 6 and the second computing node 7 by two SAS signal lines. Furthermore, a first working state of the first computing node 6 is synchronized with a second working state of the second computing node 7 by the network interface controller 9. When the first computing node 6 fails, the second computing node 7 is responsible for monitoring the status of the hard disk assembly 8.

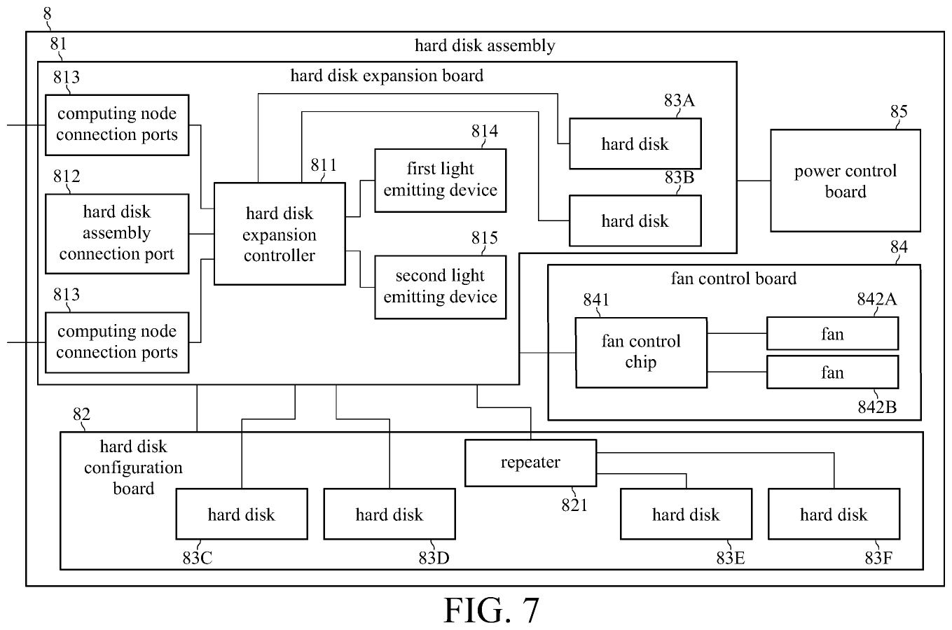

FIG. 7 is a functional block diagram of the circuit of a hard disk assembly of FIG. 6. In addition to the hard disk expansion board 81, each of the hard disk assemblies 8 further comprises a hard disk configuration board 82, a plurality of hard disks 83A-83F, a fan control board 84 and a power control board 85. The configuration structures of the hard disk expansion board 81, the hard disk configuration board 82, the hard disks 83A-83F, the fan control board 84 and the power control board 85 are similar to those of the hard disk expansion board 31, the hard disk configuration board 32, the hard disks 33A-33F, the fan control board 34 and the power control board 35 of FIG. 2. The difference between FIG. 2 and FIG. 7 is that the hard disk expansion board 81 is further provided with a first light emitting device 814 and a second light emitting device 815. The first light emitting device 814 is a light emitting diode that can emit red light, and the second light emitting element 815 is a light emitting diode that can emit green light. The hard disk expansion controller 811 is electrically connected to the first light emitting device 814 and the second light emitting device 815 by a general-purpose input/output (GPIO). When one of the computing node connection port 813 is unsuccessfully connected to the first computing node 6 (or the second computing node 7), the hard disk expansion controller 811 drives the first light emitting device 814 to emit the red light. When the computing node connection port 813 is successfully connected to the first computing node 6 (or the second computing node 7), the hard disk expansion controller 811 drives the second light emitting device 815 to emit the green light. When the computing node connection port 813 is successfully connected to the first computing node 6 (or the second computing node 7) and the first computing node 6(or the second computing node 7) transmits data to the hard disk expansion controller 811, the hard disk expansion controller 811 drives the second light emitting device 815 to emit the green light at a preset flashing frequency.

The fan control board 84 is provided with a fan control chip 841 and a plurality of fans 842A-842B. The fan control chip 841 is a complex programmable logic device (CPLD), and the fan control chip 841 is electrically connected to the fans 842A-842B and the hard disk expansion controller 811. The first computing node 6 and the second computing node 7 obtain fan state information of each of the fans 842A-842B by the hard disk expansion controller 811. The first computing node 6 and the second computing node 7 can also update firmware of the fan control chip 841 by the hard disk expansion controller 811. In addition, when the hard disk expansion controller 811 is abnormal, the fan control chip 841 will control the fans 842A-842B according to safety specifications.

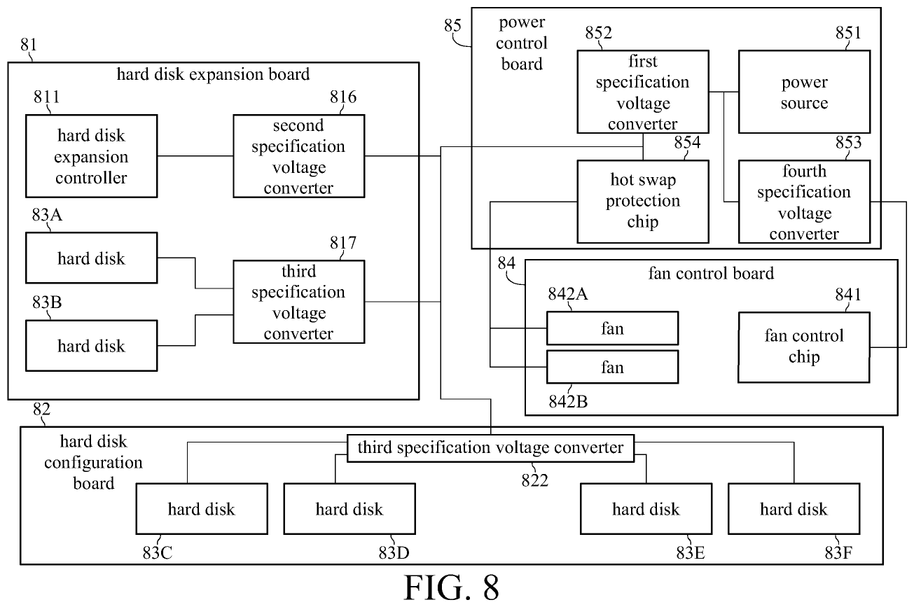

FIG. 8 is a power transmission configuration diagram of the hard disk assembly of FIG. 6. As shown in FIG. 8, the power control board 85 is provided with a power source 851 and a first specification voltage converter 852, the output voltage of the power source 851 is 48V, the first specification voltage converter 852 is a 48V to 12V converter, and the first specification voltage converter 852 has an input terminal and an output terminal, and the input terminal of the first specification voltage converter 852 is electrically connected to the power source 851. The hard disk expansion board 81 is provided with a second specification voltage converter 816 and a third specification voltage converter 817, and the hard disk configuration board 82 is provided with a repeater 821 and another third specification voltage converter 822, wherein the second specification voltage converter 822 is a 12V to 1.8V converter, and the third specification voltage converters 817 and 822 are 12V to 5V converters respectively. The second specification voltage converter 816 has an input terminal and an output terminal. The input terminal of the second specification voltage converter 816 is electrically connected to the output terminal of the first specification voltage converter 852, and the output terminal of the second specification voltage converter 816 is electrically connected to the hard disk expansion controller 811. The third specification voltage converter 817 has an input terminal and an output terminal. The input terminal of the third specification voltage converter 817 is electrically connected to the output terminal of the first specification voltage converter 852, and the output terminal of the third specification voltage converter 817 is electrically connected to the hard disks 83A-83B. The third specification voltage converter 822 has an input terminal and an output terminal. The input terminal of the third specification voltage converter 822 is electrically connected to the output terminal of the first specification voltage converter 852, and the output terminal of the third specification voltage converter 822 is electrically connected to the hard disks 83C-83F.

The power control board 85 is further provided with a fourth specification voltage converter 853 and a hot swap protection chip 854. The fourth specification voltage converter 853 is a 48V to 3.3V converter, and the fourth specification voltage converter 853 has an input terminal and an output terminal. The input terminal of the fourth specification converter 853 is electrically connected to the power source 851, and the output terminal of the fourth specification voltage converter 853 is electrically connected to the fan control chip 841 of the fan control board 84. The hot swap protection chip 854 has an input terminal and an output terminal. The input terminal of the hot swap protection chip 854 is electrically connected to the output terminal of the first specification voltage converter 852, and the output terminal of the hot swap protection chip 854 is electrically connected the fans 842A-842B mounted on the fan control board 84.

In view of the above description, all of the hard disks are concentrated in the hard disk assembly and the computing node is not provided with any hard disk, thereby increasing the total number of hard disks that can be accommodated in the server. In addition, the computing node and the hard disk assembly may be used as independent modular nodes for being purchased individually. Besides convenient management, the cost for manufacturing the server may be reduced. Furthermore, according to the needs of business applications or the needs of power supply and load bearing of the server room, the ratio of the number of computing nodes to the number of hard disk assemblies may be flexibly configured to optimize the overall operating performance of the server. In addition, the first computing node is synchronized with the second computing node under normal conditions. When the first computing node or the second computing node fails, the other computing node can be responsible for monitoring and obtaining the hard disk state information, fan status information and various sensor information of the hard disk assembly, which can improve the reliability and security of the server.

What is claimed is:

1. A server comprising:
a cabinet provided with a computing node accommodating slot and a plurality of hard disk accommodating slots;
a computing node assembled in the computing node accommodating slot, wherein the computing node is not provided with any hard disk; and
a plurality of hard disk assemblies respectively assembled in the plurality of hard disk accommodating slots, wherein each of the plurality of hard disk assemblies has a plurality of hard disks, and the plurality of hard disks is electrically connected to the computing node.

2. The server according to claim 1, wherein each of the hard disk assemblies further comprises a hard disk expansion board, the hard disk expansion board is provided with a hard disk expansion controller, the hard disk expansion controller is electrically connected to the hard disks and the computing node, and the computing node obtains hard disk state information of each of the hard disks via the hard disk expansion controller.

3. The server according to claim 1, wherein each of the hard disk assemblies further comprises a hard disk expansion board, the hard disk expansion board is provided with a hard disk expansion controller, a computing node connection port, a first light emitting device and a second light emitting device, the computing node connection port, the first light emitting device and the second light emitting device are electrically connected to the hard disk expansion controller, the hard disk expansion controller drives the first light emitting device to emit first color light when the computing node is unsuccessfully connected to the computing node connection port, and the hard disk expansion controller drives the second light emitting device to emit second color light when the computing node is successfully connected to the computing node connection port.

4. The server according to claim 1, wherein each of the hard disk assemblies further comprises a power control board and a hard disk expansion board, the power control board is provided with a power source and a first specification voltage converter, the hard disk expansion board is provided with a hard disk expansion controller, a second specification voltage converter and a third specification voltage converter, the power source is electrically connected to the second specification voltage converter and the third specification voltage converter by the first specification voltage converter, and the second specification voltage converter is further electrically connected to the hard disk expansion controller, and the third specification voltage converter is further electrically connected to the hard disks.

5. The server according to claim 1, wherein each of the hard disk assemblies further comprises a hard disk expansion board, a plurality of fans and a fan control board, the hard disk expansion board is provided with a hard disk expansion controller, the fan control board is provided with a fan control chip, the fan control chip is electrically connected to the plurality of fans and the hard disk expansion controller, and the computing node transmits an updated program to the fan control chip by the hard disk expansion controller and obtains fan state information from each of the fans.

6. The server according to claim 1, further comprising an inter-integrated circuit bus expansion board, the inter-integrated circuit bus expansion board is provided with a computing node connection port and a plurality of hard disk assembly connection ports, the computing node is electrically connected to the computing node connection port, and each of the hard disk assembly connection ports is electrically connected to one of the hard disk assemblies.

7. A server comprising:
a cabinet provided with a first computing node accommodating slot, a second computing node accommodating slot and a hard disk accommodating slot;
a first computing node assembled in the first computing node accommodating slot, wherein the first computing node is not provided with any hard disk; and
a second computing node assembled in the second computing node accommodating slot, wherein the second computing node is not provided with any hard disk;
a network interface controller connected to the first computing node and the second computing node, wherein a first working state of the first computing node is synchronized with a second working state of the second computing node; and
a hard disk assembly assembled in the hard disk accommodating slot, wherein the hard disk assembly comprises a plurality of hard disks, and the hard disks are electrically connected to the first computing node and the second computing node.

8. The server according to claim 7, wherein the hard disk assembly further comprises a hard disk expansion board, the hard disk expansion board is provided with a hard disk expansion controller, the hard disk expansion controller is electrically connected to the hard disks, the first computing node and the second computing node, and the first computing node and second computing node obtains hard disk state information of each of the hard disks by the hard disk expansion controller.

9. The server according to claim 7, wherein the hard disk assembly further comprises a power control board and a hard disk expansion board, the power control board is provided with a power source and a first specification voltage converter, the hard disk expansion board is provided with a hard disk expansion controller, a second specification voltage converter and a third specification voltage converter, the power source is electrically connected to the second specification voltage converter and the third specification voltage converter by the first specification voltage converter, the second specification voltage converter is further electrically connected to the hard disk expansion controller, and the third specification voltage converter is further electrically connected to the hard disks.

10. The server according to claim 7, wherein the hard disk assembly further comprises a hard disk expansion board, a plurality of fans and a fan control board, the hard disk expansion board is provided with a hard disk expansion controller, the fan control board is provided with a fan control chip, the fan control chip is electrically connected to the plurality of fans and the hard disk expansion controller, the first computing node or the second computing node transmits an updated program to the fan control chip by the hard disk expansion controller, and the first computing node and the second computing node obtain fan state information from each of the fans.
